(19) United States
(12) Patent Application Publication
(10) Pub. No.: US 2018/0287016 A1
(43) Pub. Date: Oct. 4, 2018

(54) SEMICONDUCTOR LIGHT-EMITTING DEVICE

(71) Applicant: TOYODA GOSEI CO., LTD., Kiyosu-shi (JP)

(72) Inventors: Takashi MIZOBUCHI, Kiyosu-shi (JP); Yohei SAMURA, Kiyosu-shi (JP)

(21) Appl. No.: 15/908,638

(22) Filed: Feb. 28, 2018

(30) Foreign Application Priority Data
Mar. 29, 2017 (JP) 2017-064772

(51) Int. Cl. H01L 33/46; H01L 33/24; H01L 33/38

(52) U.S. Cl. CPC H01L 33/46; H01L 33/24; H01L 2933/0016; H01L 2933/0025; H01L 33/385

(57) ABSTRACT

The light-emitting device includes a dielectric multilayer film on a second surface having a rectangular shape, and DBR at an opposite surface. The length of a specific side of the rectangular shape is 50 μm to 250 μm. A middle point of a side perpendicular to the specific side on the rectangular shape is defined as Q1, a line connecting the center point and the middle point Q1 is defined as M1, an angle formed between the line M1 and the center plane is defined as α. A middle point of the specific side on the rectangular shape is defined as Q3, a line connecting the center point and the middle point Q3 is defined as M2, and an angle formed between the line M2 and the center plane is defined as β. α and β satisfy the following equations.

0.6≤tan(α)≤1.0

0.6≤tan(β)≤1.0

### BACKGROUND OF THE INVENTION

### Field of the Invention

The present techniques relate to a semiconductor light-emitting device.

### Background Art

In a backlight of electronic equipment, semiconductor light-emitting devices are often disposed with a sufficient distance between the devices. The light emitted from the semiconductor light-emitting device is easily released from an axial upward direction perpendicular to the light-emitting surface to the outside of the device. Therefore, brightness difference becomes large between a portion having the semiconductor light-emitting device and a portion not having the semiconductor light-emitting device.

For example, Japanese Patent Application Laid-Open (kokai) No. 2001-7399 discloses a semiconductor light-emitting device in which light is reflected by an electrode. In the semiconductor light-emitting device, most of the light components are extracted along an axial upward direction (front direction). Therefore, light having a wide distribution can be obtained by using a lens. A fluorescent material or others may be used instead of lens.

However, in this case, the size of the semiconductor light-emitting device is increased by the lens or fluorescent material used. Recently, the semiconductor light-emitting device is required to have a wide light distribution without using the lens or fluorescent material due to demand for downsizing of electronic equipment.

### SUMMARY OF THE INVENTION

The present techniques have been conceived for solving the aforementioned problems involved in conventional techniques. Thus, an object of the present techniques is to provide a small-sized semiconductor light-emitting device having a wide light distribution and a production method therefor.

In a first aspect of the present techniques, there is provided a semiconductor light-emitting device comprising: a substrate having a first surface and a second surface, the second surface having a rectangular shape including a square shape; an n-type semiconductor layer formed on the first surface of the substrate; a light-emitting layer formed on the n-type semiconductor layer; a p-type semiconductor layer formed on the light-emitting layer; a dielectric multilayer film formed on the second surface of the substrate, the dielectric multilayer film having a light extraction surface; and a distributed bragg reflector at a position on the opposite side of the dielectric multilayer film when viewed from the light-emitting layer. The length of a specific side of the rectangular shape is 50 μm to 250 μm, the specific side being defined as one side when the lengths of four sides specifying the rectangular shape are all equal, and defined as a long side when the lengths of four sides are different. When an area of a surface of the dielectric multilayer film on the second surface is defined as surface area Sdm, and a total area of four side surfaces of the semiconductor light-emitting device is defined as side surface area Ssub, the side surface existing between the second surface and a center plane of the light-emitting layer, the center plane passing a center point of the light-emitting layer and being parallel to the second surface, the surface area Sdm and the side surface area Ssub satisfy the following equation,

1.2≤Ssub/Sdm≤2.0, and

when a middle point of a side perpendicular to the specific side on the rectangular shape is defined as Q1, a line connecting the center point and the middle point Q1 is defined as M1, and an angle formed between the line M1 and the center plane is defined as θ, the θ satisfies the following equation.

0.6≤tan(θ)≤1.0

In a second aspect of the present techniques, there is provided a semiconductor light-emitting device comprising: a substrate having a first surface and a second surface, the second surface having a rectangular shape including a square shape; an n-type semiconductor layer formed on the first surface of the substrate; a light-emitting layer formed on the n-type semiconductor layer; a p-type semiconductor layer formed on the light-emitting layer; a dielectric multilayer film formed on the second surface of the substrate, the dielectric multilayer film having a light extraction surface; and a distributed bragg reflector at a position on the opposite side of the dielectric multilayer film when viewed from the light-emitting layer. The length of a specific side of the rectangular shape is 50 μm to 250 μm, the specific side being defined as one side when the lengths of four sides specifying the rectangular shape are all equal, and defined as a long side when the lengths of four sides are different. when a middle point of a side perpendicular to the specific side on the rectangular shape is defined as Q1, a line connecting a center point of the light-emitting layer and the middle point Q1 is defined as M1, an angle formed between the line M1 and a center plane is defined as α, the center plane passing the center point and being parallel to the second surface, a middle point of the specific side on the rectangular shape is defined as Q3, a line connecting the center point and the middle point Q3 is defined as M2, and an angle formed between the line M2 and the center plane is defined as β, the α and the β satisfy the following equations, respectively.

0.6≤tan(α)≤1.0

0.6≤tan(β)≤1.0

In the semiconductor light-emitting device, a part of light is reflected on the light extraction surface toward the semiconductor layer by the dielectric multilayer film. Therefore, the components of light emitted in an axial upward direction from the light-emitting layer are suppressed. A part of the light repeatedly reflected between the dielectric multilayer film and the distributed bragg reflector, is extracted from the side surface of the substrate to the outside of the device. Therefore, the components of the light extracted from the side surface of the substrate to the outside of the device are increased. Thus, the semiconductor light-emitting device has a sufficiently wide light distribution.

A third aspect of the present techniques is drawn to a specific embodiment of the semiconductor light-emitting device according to the second aspect, wherein the α and the β satisfy the following equations, respectively.

0.7≤tan(α)≤0.9

0.7≤tan(β)≤0.9

A fourth aspect of the present techniques is drawn to a specific embodiment of the semiconductor light-emitting device according to the first or second aspect, wherein the rectangular shape is the square shape.

A fifth aspect of the present techniques is drawn to a specific embodiment of the semiconductor light-emitting device according to the second aspect, wherein the dielectric multilayer film has a characteristic of transmitting light at a center area thereof, and reflecting light at a region other than the center area.

A sixth aspect of the present techniques is drawn to a specific embodiment of the semiconductor light-emitting device according to the second aspect, wherein the semiconductor light-emitting device has a light distribution characteristic that the intensity of the light emitted from the light extraction surface has the maximum value at an emission angle range of 65° to 75°.

An seventh aspect of the present techniques is drawn to a specific embodiment of the semiconductor light-emitting device according to the second aspect, wherein the device comprises a metal reflecting layer formed on the distributed bragg reflector.

An eighth aspect of the present techniques is drawn to a specific embodiment of the semiconductor light-emitting device according to the second aspect, wherein the semiconductor light-emitting device further includes an n-electrode electrically connected to the n-type semiconductor layer and a p-electrode electrically connected to the p-type semiconductor layer. The n-electrode and the p-electrode cover a part of the side surface of the substrate.

In a ninth aspect of the present techniques, there is provided a method for producing a semiconductor light-emitting device, the method comprising a semiconductor layer formation step of forming a semiconductor layer having an n-type semiconductor layer, a light-emitting layer, and a p-type semiconductor layer on the first surface of a growth substrate having a first surface and a second surface, a semiconductor layer dividing step of dividing a semiconductor layer by removing the entire thickness of the semiconductor layer and a part of the thickness of the growth substrate from the semiconductor layer side, a distributed bragg reflector formation step of forming a distributed bragg reflector on the p-type semiconductor layer side, an electrode formation step of forming an n-electrode being electrically connected to the n-type semiconductor layer and a p-electrode being electrically connected to the p-type semiconductor layer, a polishing step of polishing the second surface side of the growth substrate, and a dielectric multilayer film formation step of forming a dielectric multilayer film on the polished second surface. In the polishing step, when the area of the dielectric multilayer film on the light extraction surface side is defined as surface area Sdm, and the area of the side surface of the semiconductor light-emitting device passing from the second surface to the center of the light-emitting layer and being parallel to the second surface is defined as side surface area Ssub, the growth substrate is polished so that the surface area Sdm and the side surface area Ssub satisfy the following equation.

1.2≤Ssub/Sdm≤2.0

The present techniques, disclosed in the specification, provide a small-sized semiconductor light-emitting device having a wide light distribution and a production method therefor.

### BRIEF DESCRIPTION OF THE DRAWINGS

Various other objects, features, and many of the attendant advantages of the present techniques will be readily appreciated as the same becomes better understood with reference to the following detailed description of the preferred embodiments when considered in connection with the accompanying drawings, in which:

FIG. 1 is a schematic view of the structure of a light-emitting device according to Embodiment 1;

FIG. 2 is a schematic view showing the light-emitting device according to Embodiment 1 when viewed from the opposite side of a light extraction surface;

FIG. 3 is a view of the light-emitting device according to Embodiment 1 when viewed from the light extraction surface;

FIG. 4 is a cross sectional view of FIG. 3, taken along line IV-IV;

FIG. 5 is a view showing light paths of a light emitted from the light-emitting layer in the light-emitting device according to Embodiment 1;

FIG. 6 is a view showing a method for producing the light-emitting device according to Embodiment 1 (part 1);

FIG. 7 is a view showing a method for producing the light-emitting device according to Embodiment 1 (part 2);

FIG. 8 is a view showing a method for producing the light-emitting device according to Embodiment 1 (part 3);

FIG. 9 is a view showing a method for producing the light-emitting device according to Embodiment 1 (part 4);

FIG. 10 is a view showing a method for producing the light-emitting device according to Embodiment 1 (part 5);

FIG. 11 is a view showing a method for producing the light-emitting device according to Embodiment 1 (part 6);

FIG. 12 is a view showing a method for producing the light-emitting device according to Embodiment 1 (part 7);

FIG. 13 is a view showing a method for producing the light-emitting device according to Embodiment 1 (part 8);

FIG. 14 is a view showing a light-emitting device according to a modification of Embodiment 1 when viewed from a light extraction surface;

FIG. 15 is a view showing the light-emitting device according to a modification of Embodiment 1 when viewed from the opposite side of the light extraction surface (part 1);

FIG. 16 is a view showing the light-emitting device according to a modification of Embodiment 1 when viewed from the opposite side of the light extraction surface (part 2);

FIG. 17 is a view showing a substrate having an uneven shape of the light-emitting device according to a modification of Embodiment 1 (part 1);

FIG. 18 is a view showing a substrate having an uneven shape of the light-emitting device according to a modification of Embodiment 1 (part 2); and

FIG. 19 is a graph showing light distribution of a semiconductor light-emitting device in Embodiments.

### DETAILED DESCRIPTION OF PREFERRED EMBODIMENTS

With reference to the drawings, specific embodiment of the semiconductor light-emitting device and the production method therefor as an example will next be described in detail. However, this embodiment should not be construed as limiting the techniques thereto. The below-described depositing structure of the layers of the semiconductor light-emitting device and the electrode structure are given only for the illustration purpose, and other depositing structures differing therefrom may also be employed. The thickness of each of the layers shown in the drawings is not an actual value, but a conceptual value.

### Embodiment 1

### 1. Semiconductor Light-Emitting Device

FIG. 1 is a schematic view of the structure of a light-emitting device 100 according to Embodiment 1. The light-emitting device 100 is a flip-chip type semiconductor light-emitting device having a light extraction surface on the opposite side of a semiconductor layer when viewed from a substrate. As shown in FIG. 1, the light-emitting device 100 includes a dielectric multilayer film DM1, a substrate 110, a buffer layer 120, an n-type contact layer 130, an n-side cladding layer 140, a light-emitting layer 150, a p-side cladding layer 160, a p-type contact layer 170, a transparent electrode TE1, a distributed bragg reflector DBR1, a p-electrode P1, and an n-electrode N1.

The substrate 110 is a sapphire substrate for transmitting a light emitted from the light-emitting layer 150 to the opposite side of the semiconductor layer. The substrate 110 has a rectangular parallelopiped shape. The substrate 110 has a first surface 110a and a second surface 110b. The first surface 110a is a main surface for forming a semiconductor layer thereon. The second surface 110b is a surface opposite to the first surface 110a. That is, the second surface 110b is a surface on the light extraction surface side. The first surface 110a and the second surface 110b are both flat. A cross section parallel to the first surface 110a of the substrate 110 has a square shape. The length of one side of the square shape, that is, the length of one side of the first surface 110a is 50 μm to 250 μm.

The dielectric multilayer film DM1 has a light extraction surface LE1. The dielectric multilayer film DM1 is a film formed by depositing at least two types of dielectric films with different refractive indices. The dielectric multilayer film DM1 is used for transmitting a part of the light emitted from the light-emitting layer 150 and reflecting the remaining part of the light emitted from the light-emitting layer 150. The dielectric multilayer film DM1 is formed on the second surface 110b of the substrate 110. The dielectric multilayer film DM1 is a multilayer film formed by alternately depositing, for example, SiO₂ and TiO₂. The dielectric multilayer film DM1 may be made of a combination of any materials other than these. Moreover, the dielectric multilayer film DM1 may have any number of layers deposited.

The buffer layer 120 is formed on the first surface 110a of the substrate 110. The buffer layer 120 is made of, for example, a low temperature formed AlN layer or a low temperature formed GaN layer. The n-type contact layer 130 is a semiconductor layer in contact with the n-electrode N1. The n-type contact layer 130 is formed on the buffer layer 120. The n-type contact layer 130 is made of, for example, n-type GaN. The n-side cladding layer 140 is formed on the n-type contact layer 130. The n-side cladding layer 140 has a superlattice layer formed by repeatedly forming an n-type GaN layer and an n-type InGaN layer. The n-type contact layer 130 and the n-side cladding layer 140 are n-type semiconductor layers. The n-type semiconductor layer is formed on the first surface 110a of the substrate 110.

The light-emitting layer 150 is a semiconductor layer for emitting light through recombination of holes and electrons. The light-emitting layer 150 is formed on the n-side cladding layer 140. The light-emitting layer 150 has a well layer and a barrier layer. The well layer is, for example, an InGaN layer. The barrier layer is, for example, a GaN layer or an AlGaN layer.

The p-side cladding layer 160 is formed on the light-emitting layer 150. The p-side cladding layer 160 is formed by alternately forming, for example, a p-type InGaN layer and a p-type AlGaN layer. The p-type contact layer 170 is a semiconductor layer in contact with the transparent electrode TE1. The p-type contact layer 170 is formed on the p-side cladding layer 160. The p-side cladding layer 160 and the p-type contact layer 170 are a p-type semiconductor layer.

The transparent electrode TE1 is an electrode used for making a contact with the p-type contact layer 170. The transparent electrode TE1 is formed on the p-type contact layer 170. The transparent electrode TE1 is made of IZO. A transparent conductive oxide such as ITO, ICO, ZnO, TiO₂, NbTiO2, and TaTiO2 may be used other than IZO.

The distributed bragg reflector DBR1 is formed on the transparent electrode TE1. That is, the distributed bragg reflector DBR1 is disposed at a position opposite to the dielectric multilayer film DM1 when viewed from the light-emitting layer 150. The distributed bragg reflector DBR1 covers a part of the transparent electrode TE1, a side surface of the semiconductor layer, and a part of a side surface of the substrate 110. The distributed bragg reflector DBR1 is an insulating film. The distributed bragg reflector DBR1 has at least one thorough hole. In the at least one through hole, the transparent electrode TE1 is exposed. The distributed bragg reflector DBR1 is a multilayer film formed by alternately depositing, for example, SiO₂ and TiO₂. The distributed bragg reflector DBR1 is made of a combination of any materials other than these. The distributed bragg reflector DBR1 may have any number of layers deposited.

The p-electrode P1 is an electrode in contact with the transparent electrode TE1. The p-electrode P1 is in contact with the transparent electrode TE1 in a condition that the p-electrode P1 passes through the through hole of the distributed bragg reflector DBR1. Therefore, the p-electrode P1 is electrically connected to the p-type contact layer 170. The p-electrode P1 covers the side surface of the light-emitting device 100. The distributed bragg reflector DBR1 is disposed between the p-electrode P1 and the side surface of the semiconductor layer. Thus, the p-electrode P1 is not in direct contact with the semiconductor layer. That is, the p-electrode P1 covers a part of the side surface of the substrate 110 and the side surface of the semiconductor layer via the distributed bragg reflector DBR1. The p-electrode P1 is formed of a combination of at least one selected from a group consisting of Ni, Au, Ag, Co, Cr or the like. Needless to say, any material other than the above may be used.

The n-electrode N1 is an electrode conducted to the n-type contact layer 130. The n-electrode N1 is formed on and in contact with the n-type contact layer 130. The n-electrode N1 covers the side surface of the light-emitting device 100. The distributed bragg reflector DBR1 is disposed between the n-electrode N1 and the side surface of the semiconductor layer. Therefore, the n-electrode N1 is not in direct contact with the semiconductor layer. That is, the n-electrode N1 covers a part of the side surface of the substrate 110 and the side surface of the semiconductor layer via the distributed bragg reflector DBR1. The n-electrode N1 is made of a combination of at least one selected from a group consisting of Ni, Au, Ag, Co, Cr, or the like. Needless to say, a material other than the above may be used.

The above layers are provided as examples. Each layer may be made of a material other than the above. The semiconductor layer may have a layered structure different from the above.

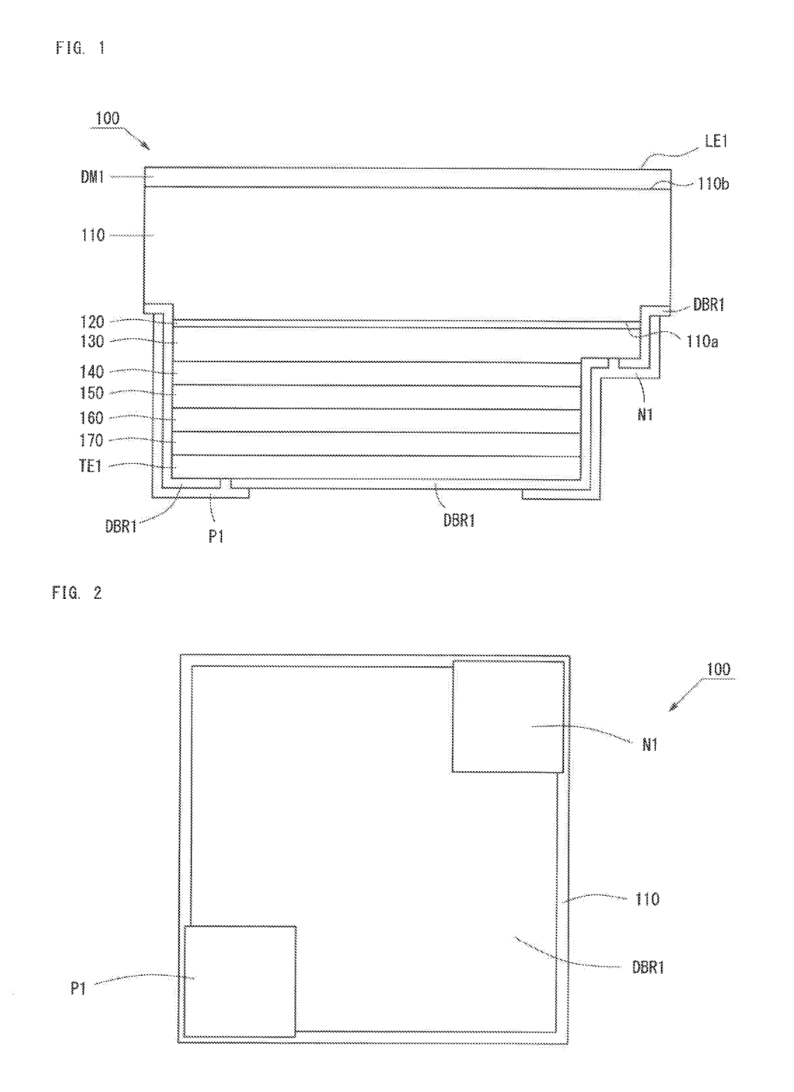

FIG. 2 is a view of the light-emitting device 100 when viewed from the opposite side of the light extraction surface LE1, i.e., a view of a back surface. As shown in FIG. 2, the p-electrode P1 and the n-electrode N1 has a square shape when viewed from the opposite side of the light extraction surface LE1 of the light-emitting device 100. The p-electrode P1 and the n-electrode N1 are disposed at diagonal positions of a rectangular shape.

### 2. Relationship Between the Light-Emitting Layer and the Sapphire Substrate

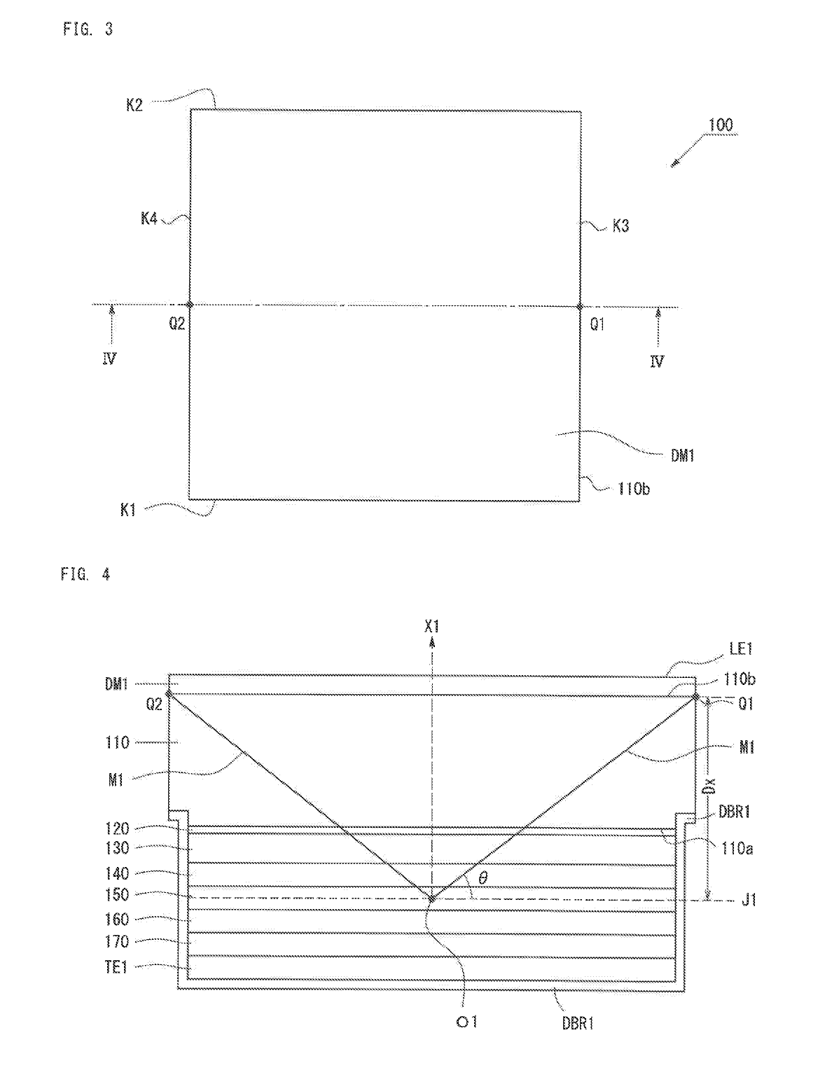

FIG. 3 is a view of the light-emitting device 100 when viewed from the light extraction surface LE1 side. As shown in FIG. 3, the light-emitting device 100 has a square shape having four sides K1, K2, K3, and K4 when viewed from the light extraction surface LE1. The sides K3 and K4 are perpendicular to the sides K1 and K2.

FIG. 4 is a cross-sectional view of FIG. 3, being cut along line IV-IV and perpendicularly to the second surface 110b. The cutting line IV-IV of FIG. 3 is parallel to one side K1 or K2 of the square shape. The center point O1 of the light-emitting layer 150 is on the cross section of FIG. 4. The center point O1 is the center of gravity of the light-emitting layer 150 having a rectangular parallelopiped shape. That is, the center point O1 is also a geometrical center of the light-emitting layer 150. The center plane J1 is a plane passing the center point O1 of the light-emitting layer 150 and being parallel to the light-emitting surface of the light-emitting layer 150. The center plane J1 is parallel to the first surface 110a and the second surface 110b.

The end points Q1 and Q2 are middle points on the sides K3 and K4 of the second surface 110b, respectively. A normal direction X1 is a direction perpendicular to the second surface 110b and the light-emitting surface of the light-emitting layer 150. A line M1 is a line connecting the center point O1 and the end point Q1. An angle θ is defined as an angle formed between the line M1 and the center plane J1 or the light-emitting surface of the light-emitting layer 150. The angle θ satisfies the following equation. The angle (π/2−θ) is the angle between the line M1 and the normal direction X1.

0.6≤tan(θ)≤1.0 (1)

The angle θ more preferably satisfies the following equation.

0.7≤tan(θ)≤0.9 (2)

### 3. Relationship Between the Surface Area of the Dielectric Multilayer Film and the Side Surface Area of the Light-Emitting Device

The area of the dielectric multilayer film DM1 on the light extraction surface LE1 side is defined as surface area Sdm. The total area of the four side surfaces of the light-emitting device 100 in the region from the second surface 110b to the center plane J1 is defined as side surface area Ssub. The surface area Sdm and the side surface area Ssub satisfy the following equation.

1.2≤Ssub/Sdm≤2.0 (3)

The surface area Sdm and the side surface area Ssub more preferably satisfy the following equation.

1.4≤Ssub/Sdm≤1.8 (4)

The length of one side K1 of the second surface 110b of the square is defined as α, and the distance between the second surface 110b and the center plane J1 is defined as Dx. The following equations are satisfied:

tan θ=2Dx/a (5)

Ssub=4a·Dx (6)

Sdm=a² (7)

Therefore,

Ssub/Sdm=2 tan(θ) (8)

Accordingly, the above equations (1) and (3) are equivalent, and the equations (2) and (4) are equivalent.

### 4. Light Emitted from the Light-Emitting Layer

FIG. 5 is a view showing light paths of a light emitted from the light-emitting layer 150. FIG. 5 is drawn by extracting the area from the center plane J1 to the dielectric multilayer film DM1 of the light-emitting device 100. In FIG. 5, an interface between the semiconductor layers and an interface between the buffer layer 120 and the substrate 110 are omitted.

As shown in FIG. 5, light L1 emitted at an angle θ1 larger than the angle θ from the center point O1 reaches the dielectric multilayer film DM1. As shown in FIG. 5, the light L1 incident on the dielectric multilayer film DM1 is reflected by the dielectric multilayer film DM1. Light L2 emitted at an angle θ2 larger than the angle θ from the center point O1 reaches the dielectric multilayer film DM1. The light L2 incident on the dielectric multilayer film DM1 is transmitted through the dielectric multilayer film DM1. In this way, a part of the light incident on the dielectric multilayer film DM1 is reflected, and the remaining part of the light is transmitted. The dielectric multilayer film DM1 is designed so as to transmit a light incident at an angle smaller than the incident angle (π/2−θ4) and reflect a light incident at an angle larger than the incident angle (π/2−θ4). However, θ1≤θ4≤θ2. θ4 is set to about 10°.

The light L1 reflected by the dielectric multilayer film DM1 is reflected by the distributed bragg reflector DBR1. Therefore, the light L1 is directed toward the light extraction surface LE1. Thus, the light reflected by the dielectric multilayer film DM1 and the distributed bragg reflector DBR1 is transmitted through the dielectric multilayer film DM1 and travels to the outside of the device, or travels from the side surface having no dielectric multilayer film DM1 to the outside of the device.

On the other hand, light L3 emitted at an angle θ3 smaller than the angle θ from the center point O1 travels from the side surface of the device to the outside of the device without being incident on the dielectric multilayer film DM1.

In this way, in the light emitted from the center point O1, the component in the normal direction X1 is attenuated and the component of the side surface direction of the device is increased. Moreover, the component in the normal direction X1 is attenuated and the component in the side surface direction of the device is increased even at places other than the center point O1 of the light-emitting layer 150.

Therefore, the intensity of the light emitted from the light-emitting device 100 has a peak at a position in the vicinity of 70° (radiation angle) from the normal direction X1. That is, the light-emitting device 100 has a sufficiently wide light distribution. The light intensity in the normal direction X1 (0°) is preferably 40% or less of the light intensity at the maximum peak value, more preferably, 20% or less of the light intensity at the maximum peak value. The light-emitting device 100 is suitable as a backlight of electronic equipment. In this case, even if the light-emitting devices 100 are disposed with sufficient intervals, a sufficient amount of light is obtained at an intermediate position between the light-emitting devices 100.

### 5. Semiconductor Light-Emitting Device Production Method

### 5-1. Semiconductor Layer Formation Step

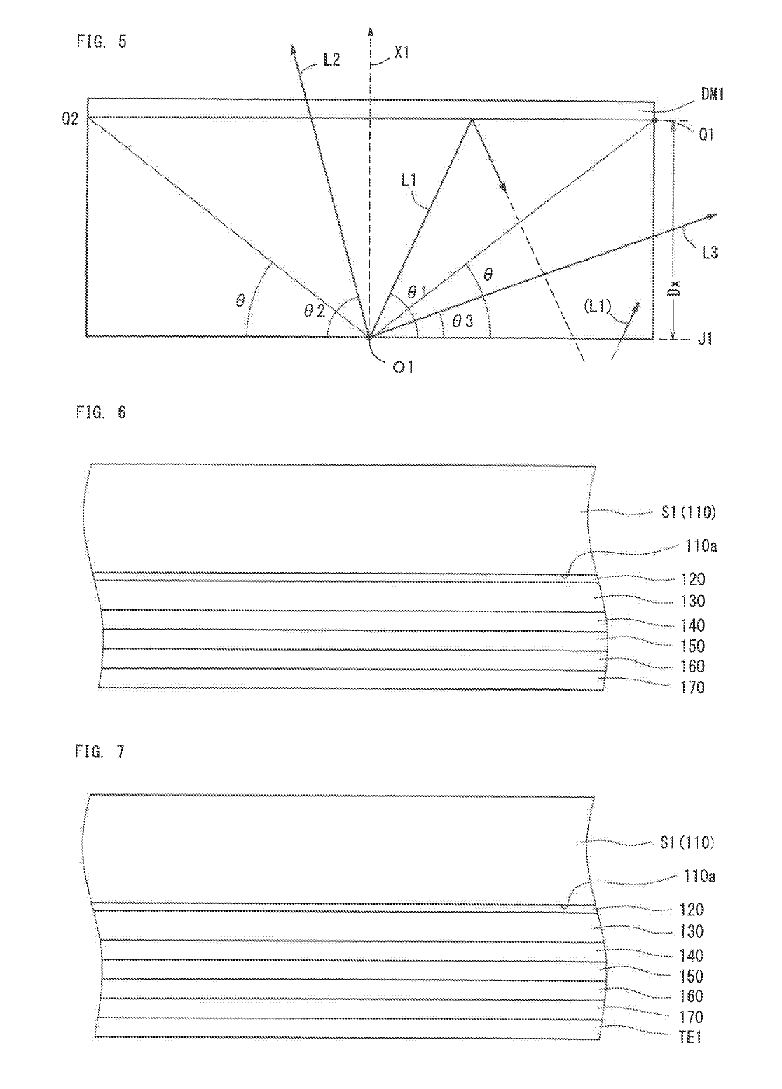

Firstly, as shown in FIG. 6, a buffer layer 120, an n-type contact layer 130, an n-side cladding layer 140, a light-emitting layer 150, a p-side cladding layer 160, and a p-type contact layer 170 are formed in this order on the first surface 110a of the growth substrate S1. The technique of formation may be MOCVD. The growth substrate S1 later becomes a substrate 110. The growth substrate S1 has a second surface. However, in this stage, the second surface of the growth substrate S1 is not the second surface 110b of the substrate 110.

### 5-2. Transparent Electrode Formation Step

Next, as shown in FIG. 7, a transparent electrode TE1 is formed on the p-type contact layer 170. The technique of formation may be sputtering.

5-3. n-Type Semiconductor Layer Exposing Step

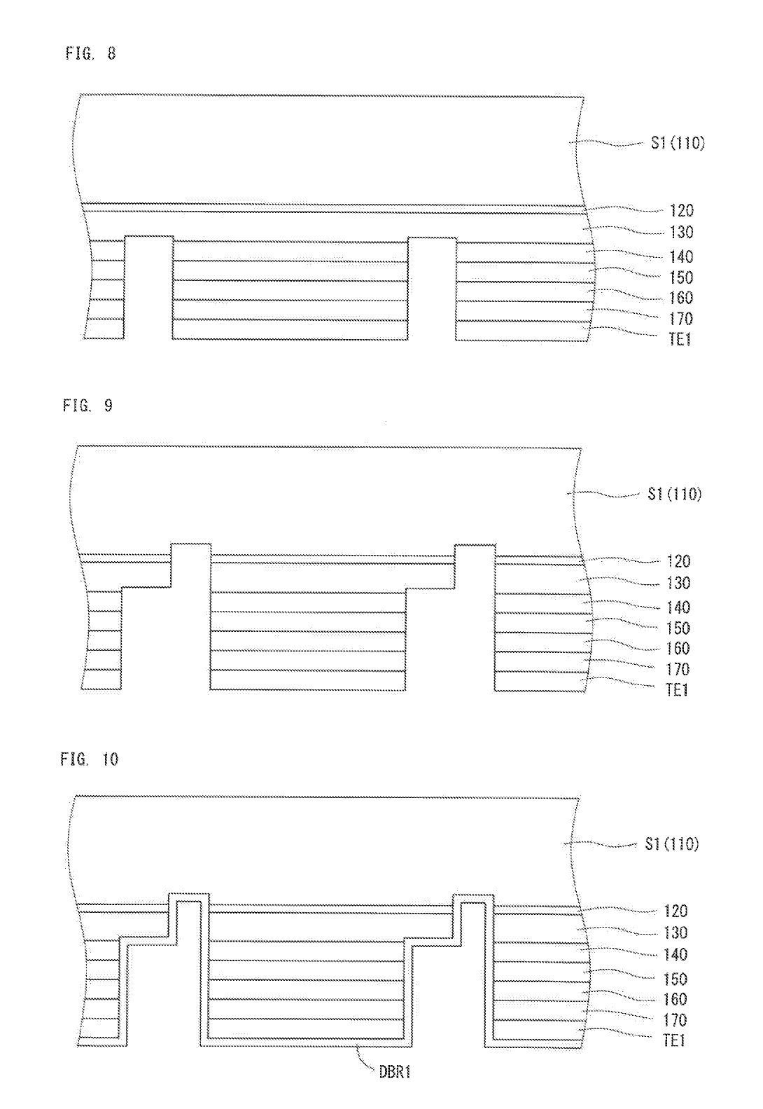

As shown in FIG. 8, trenches are formed to expose the n-type contact layer 130. The trenches are used for forming n-electrodes N1. The technique of formation may be decomposition by laser or etching.

### 5-4. Semiconductor Layer Dividing Step

As shown in FIG. 9, the semiconductor layers are divided by forming trenches. These trenches are for dividing the semiconductor layers by the size of the light-emitting device 100. These trenches are formed by removing the entire thickness of the semiconductor layers from the semiconductor layer side and a part of the thickness of the growth substrate S1. These trenches may be formed by irradiating the semiconductor layer with laser beam and removing the portion irradiated with laser beam through etching.

### 5-5. Distributed Bragg Reflector Formation Step

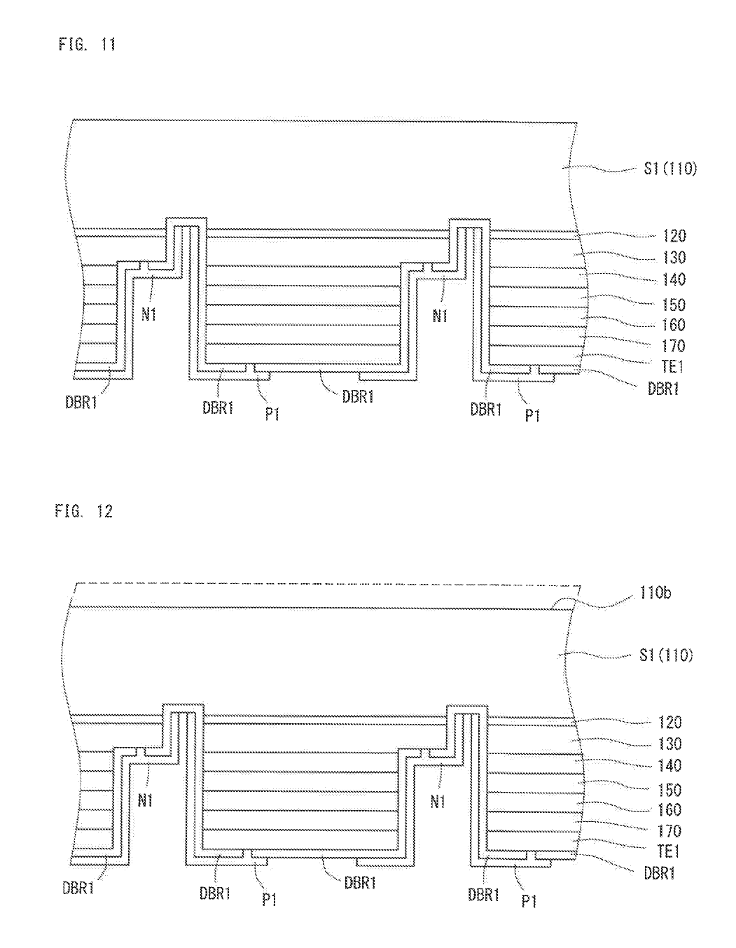

As shown in FIG. 10, a distributed bragg reflector DBR1 is formed on the transparent electrode TE1. That is, the distributed bragg reflector DBR1 is formed on the p-type semiconductor layer side by sputtering or other film deposition method. Thus, the distributed bragg reflector DBR1 is formed on the transparent electrode TE1, the side surfaces of the semiconductor layers, and the exposed surface of the growth substrate S1.

### 5-6. Electrode Formation Step

As shown in FIG. 11, a p-electrode P1 and an n-electrode N1 are formed. Firstly, a part of the distributed bragg reflector DBR1 is opened to expose the n-type contact layer 130 and the p-type contact layer 170. For example, a part of the distributed bragg reflector DBR1 may be opened by etching. Thereafter, the p-electrode P1 and the n-electrode N1 are formed. At that time, the p-electrode P1 and the n-electrode N1 are also formed via the distributed bragg reflector DBR1 on the side surfaces of the semiconductor layers and a part of the side surface of the growth substrate S1.

### 5-7. Polishing Step

As shown in FIG. 12, the surface on the side opposite to the first surface 110a of the growth substrate S1 is polished. Thus, the surface corresponding to the second surface 110b of the substrate 110 is exposed. The thickness of the growth substrate S1 after polishing is the thickness of the substrate 110.

### 5-8. Dielectric Multilayer Film Formation Step

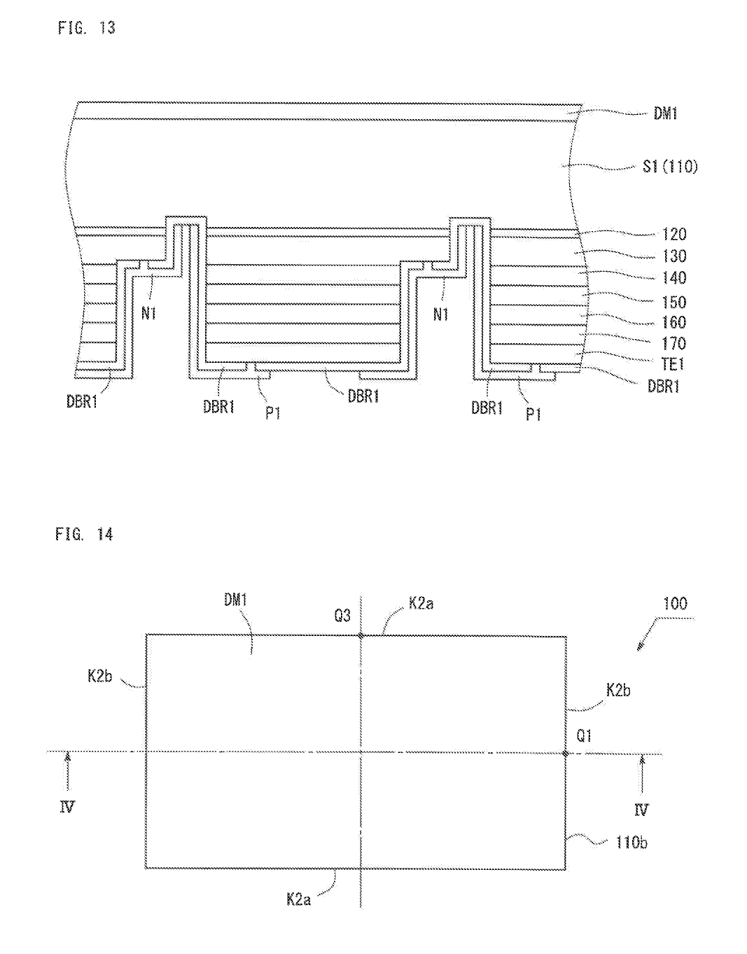

As shown in FIG. 13, a dielectric multilayer film DM1 is formed on the second surface 110b of the polished growth substrate S1 (substrate 110). The technique of formation may be sputtering or other film deposition method.

### 5-9. Device Separation Step

The growth substrate S1 is separated using a laser or a breaking device. Thus, the light-emitting device 100 is produced.

### 5-10. Other Steps

In addition to the above, a thermal treatment step or a protective film formation step may be carried out.

### 6. Effects of First Embodiment

The light-emitting device 100 of the first embodiment is a small-sized semiconductor light-emitting device whose length of one side is short. The light-emitting device 100 has a dielectric multilayer film DM1 on the light extraction surface LE1 side when viewed from the light-emitting layer 150, and a distributed bragg reflector DBR1 on the side opposite to the light extraction surface LE1 when viewed from the light-emitting layer 150.

On the light extraction surface LE1 side, a part of light is reflected toward the semiconductor layer by the dielectric multilayer film DM1. Moreover, a part of the light reflected between the dielectric multilayer film DM1 and the distributed bragg reflector DBR1 is extracted from the side surface of the substrate 110 to the outside of the device. Therefore, the components of the light emitted in a normal direction X1 from the light-emitting layer 150 are suppressed, and the components of the light traveling from the side surface of the substrate 110 to the outside of the device are increased.

Therefore, when a plurality of light-emitting devices 100 are arranged at a certain interval, the light quantity is sufficient at an intermediate position between the light-emitting devices 100.

The p-electrode P1 and the n-electrode N1 are formed on the surface and the side surface of the light-emitting device 100. Accordingly, the p-electrode P1 and the n-electrode N1 are in close contact with the distributed bragg reflector DBR1.

### 7. Modifications

### 7-1. When Light-Emitting Layer has a Rectangular Shape

FIG. 14 illustrates the case when the light-emitting layer has a rectangular shape. In this case, the light-emitting device 100 has a rectangular shape when viewed from the light extraction surface LE1 side. When viewed from the light extraction surface LE1 side, the light-emitting device 100 has two long sides K2a and two short sides K2b. The one of two long sides K2a is a specific side. In this case, a cross section parallel to the long side K2a may be as shown in FIG. 4. The cross section passes the center point O1 of the light-emitting layer 150 and is parallel to the long side K2a. The end point Q1 is a middle point of the short side K2b of the second surface 110b of the substrate 110. An angle θ formed between the line M1 connecting the center point O1 of the light-emitting layer 150 and the end point Q1 and the center plane J1 may satisfy the equation (1) or (2). The length of the long side K2a of the second surface 110b is 50 μm to 250 μm.

In the first case, only in the light distribution characteristics with respect to a direction parallel to the long side K2a, the maximum intensity value exists at a radiation angle (π/2−θ) range of 65° to 75°. The light distribution characteristics with respect to a direction parallel to the short sides K2b is not particularly limited. In this case, the length a of the long side and the distance Dx between the second surface 110b and the center plane J1 may be determined so as to satisfy the equations (1) and (3), or the equations (2) and (4). The length of the short side is not particularly limited. The length of the short side and the distance Dx may be selected in a range simultaneously satisfying the equations (1) and (3), or the equations (2) and (4).

In the second case, in both the light distribution characteristics with respect to a direction parallel to the long side K2a and the light distribution characteristic with respect to a direction parallel to the short sides K2b, the maximum intensity value exists at an angle range of 65° to 75°. The second case will be described below.

In FIG. 14, the length of the long side K2a of the second surface 110b is defined as α, and the length of the short side K2b of the second surface 110b is defined as b. The middle point of the short side K2b is defined as the end point Q1 and the middle point of the long side K2a is defined as the end point Q3. In the same way as in FIG. 4, the line connecting the center point O1 and the end point Q1 is defined as M1, and the line connecting the center point O1 and the end point Q3 is defined as M2. The angle formed between the line M1 and the center plane J1 is defined as α, and the angle formed between the line M2 and the center plane J1 is defined as β. The following equations are satisfied.

tan(α)=2Dx/a (9)

tan(β)=2Dx/b (10)

Ssub=2(a+b)Dx (11)

Sdm=ab (12)

Therefore,

Ssub/Sdm=tan(α)+tan(β) (13)

When the second surface 110b is a rectangle, the following equations are used instead of the equation (1).

0.6≤tan(α)≤1.0 (14)

0.6≤tan(β)≤1.0 (15)

When the length a of the long side, the length b of the short side, and the distance Dx are determined so as to satisfy both the equations (14) and (15), the maximum intensity value can be obtained at an emission angle range of 65° to 75° in the light distribution characteristics with respect to a direction parallel to the long side and a direction parallel to the short side. When the length of the long side K2a of the second surface 110b is 50 μm to 250 μm and the equations (14) and (15) are satisfied, the length of the short side K2b of the second surface 110b is 30 μm to 150 μm. Moreover, the following equations are used instead of the equation (2).

0.7≤tan(α)≤0.9 (16)

0.7≤tan(β)≤0.9 (17)

Thus, Ssub/Sdm satisfies the following equations having the same conditions as those of the equations (3) and (4).

1.2≤Ssub/Sdm≤2.0 (18)

1.4≤Ssub/Sdm≤1.8 (19)

### 7-2. Shape of Electrode

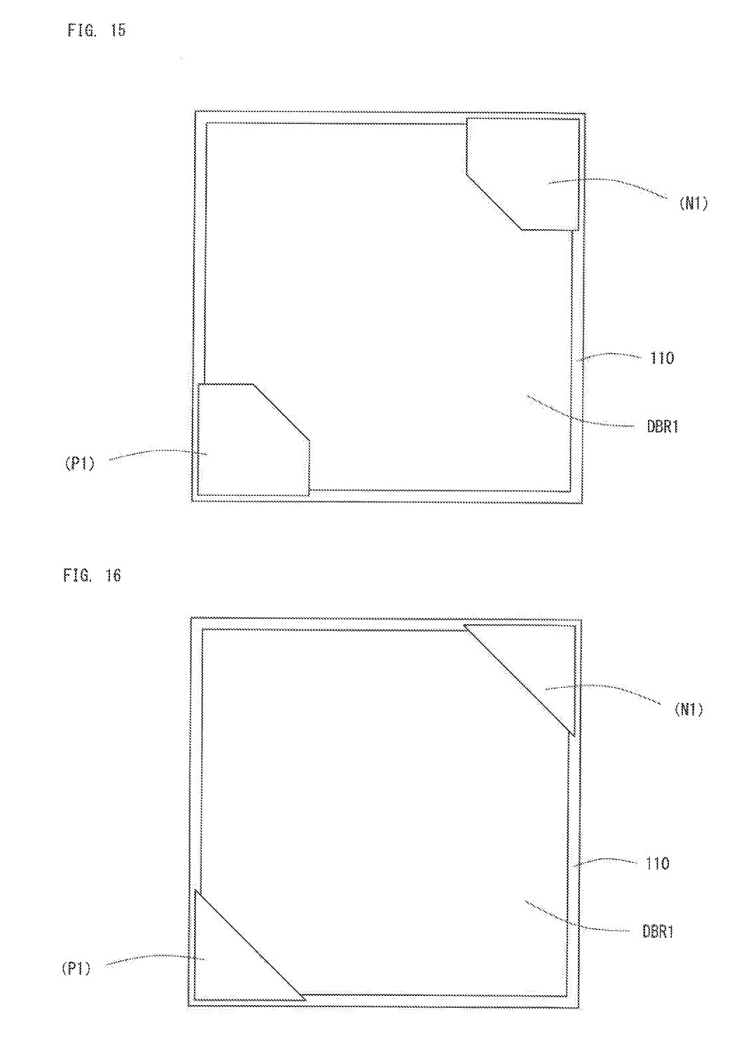

FIG. 15 is a view showing the shape of the pad electrode in a modification of Embodiment 1 (part 1). FIG. 16 is a view showing the shape of the pad electrode in a modification of Embodiment 1 (part 2). As shown in FIGS. 15 and 16, the p-electrode P1 and the n-electrode N1 may have a pentagonal, triangular, or other polygonal shape. However, the p-electrode P1 and the n-electrode N1 cover a part of the surface opposite to the light extraction surface LE1 and a part of the side surface of the light-emitting device 100.

### 7-3. Mesa Formation Step

Before and after the device dividing step, a mesa formation step of forming mesas on the semiconductor layer may be carried out. The technique of formation may be etching.

### 7-4. Uneven Shape of Substrate

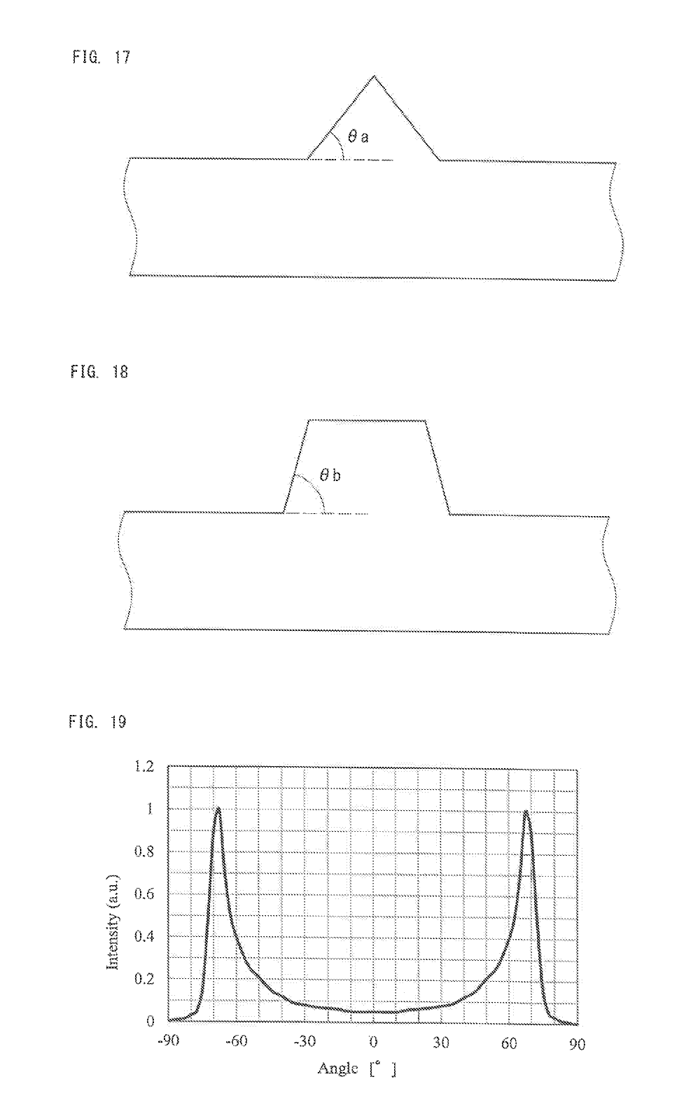

As shown in FIG. 17, an uneven shape, e.g. cone, pyramid such as hexagonal pyramid, may be formed at least one of the first surface 110a and the second surface 110b of the substrate 110. An uneven shape, e.g., truncated cone, truncated pyramid such as hexagonal truncated pyramid, may be formed as shown in FIG. 18. An angle θb formed between the flat surface and the inclined surface of the uneven shape in FIG. 18 is larger than an angle formed between the flat surface and the inclined surface in FIG. 17. When the angle formed between the flat surface and the inclined surface is large as shown in FIG. 18, the light-emitting device has a wide light distribution.

### 7-5. Insulating Layer

Another insulating layer may be formed on the distributed bragg reflector DBR1 to enhance insulation between the electrode and the semiconductor layer. The distributed bragg reflector DBR1 may be formed only on the transparent electrode TE1, and may not be formed on the side surface of the semiconductor layers. In that case, an insulating layer is preferably formed separately on the side surface of the semiconductor layers between the electrode and the semiconductor layer.

### 7-6. Reflector

A metal reflecting layer may be formed on the surface opposite to the transparent electrode TE1 of the distributed bragg reflector DBR1. The metal reflecting layer is formed of Ag, Al, or an alloy containing these. Thus, light transmitted through the distributed bragg reflector DBR1 can be reflected.

### 7-7. Combination

The above-described modifications may be combined appropriately.

### 8. Summary of the First Embodiment

The light-emitting device 100 of the first embodiment is a small-sized semiconductor light-emitting device whose length of one side is short. The light-emitting device 100 has the dielectric multilayer film DM1 on the light extraction surface LE1 side when viewed from the light-emitting layer 150, and the distributed bragg reflector DBR1 on the side opposite to the light extraction surface LE1 when viewed from the light-emitting layer 150.

Accordingly, a part of light is reflected toward the semiconductor layer by the dielectric multilayer film DM1 on the light extraction surface LE1 side. A part of the light reflected between the dielectric multilayer film DM1 and the distributed bragg reflector DBR1 is extracted to the outside of the device from the side surface of the substrate 110. Therefore, the components of light emitted in the normal direction X1 from the light-emitting layer 150 are suppressed, and the components of the light traveling from the side surface of the substrate 110 to the outside of the device are increased.

Notably, the aforementioned embodiments are given for the illustration purpose. Thus, needless to say, various modifications and variations can be made, so long as they fall within the scope of the present technique. The film formation technique is not limited to metal-organic chemical vapor deposition (MOCVD). Other similar techniques may be employed, so long as they employ carrier gas in crystal growth. Alternatively, the semiconductor layers may be formed through another epitaxial growth technique such as liquid phase epitaxy or molecular beam epitaxy.

### EXAMPLES

### 1. Experiment

### 1-1. Production of Sample

A light-emitting device was produced using a square substrate having a length of one side of 180 μm. Accordingly, the second surface is a square shape. A dielectric multilayer film was formed on the light extraction surface side of the light-emitting device. The dielectric multilayer film was formed by alternately depositing SiO₂ and TiO₂. A distributed bragg reflector was formed on the opposite side of the substrate when viewed from the light-emitting layer. The distributed bragg reflector was formed by alternately depositing SiO₂ and TiO₂. Four types of light-emitting devices having different thicknesses of the sapphire substrate were produced. In these four types of the light-emitting devices, a distance Dx between the surface of the substrate (corresponding to the second surface 110b) having the dielectric multilayer film thereon and the center surface of the light-emitting layer (corresponding to the center plane J1) is 40 μm, 60 μm, 80 μm, and 100 μm. These light-emitting devices (samples) are listed in Table 1.

TABLE 1

| | Length of | | | |
|---|---|---|---|---|
| | one side | Thickness | | |
| Sample name | (μm) | Dx (μm) | tanθ | Ssub/Sdm |
| Sample A1 | 180 | 40 | 0.44 | 0.89 |
| Sample A2 | 180 | 60 | 0.67 | 1.33 |
| Sample A3 | 180 | 80 | 0.89 | 1.78 |
| Sample A4 | 180 | 100 | 1.11 | 2.22 |

### 1-2. Light Distribution

In the light-emitting device (sample A2) having the distance Dx of 60 μm, the light intensity has a peak at 70° from the normal direction X1. The light distribution in this case is shown in FIG. 19. In the light-emitting device for a backlight, the light intensity preferably has a peak in the vicinity of 70°. Moreover, as shown in FIG. 19, the light intensity at the normal direction X1 (0°) is preferably 40% or less and, more preferably, 20% or less of the light intensity at the maximum peak value. The sample A2 satisfies the equation (1) and the sample A3 satisfies the equation (1) and the equation (2).

### 2. Calculation

### 2-1. Calculation Method

Next, calculation was performed. For simplification, the material between the dielectric multilayer film and the distributed bragg reflector was approximated as sapphire. Under these conditions, the angles from the normal direction X11 at which the light intensity has a peak were calculated.

### 2-2. Calculation Results

Table 2 shows the samples having a light intensity peak at an angle range of 65° to 75°.

TABLE 2

| | Length of | | | |
|---|---|---|---|---|
| | one side | Thickness | | |
| Sample name | (μm) | Dx (μm) | tanθ | Ssub/Sdm |
| Sample B1 | 100 | 40 | 0.8 | 1.6 |
| Sample B2 | 150 | 60 | 0.8 | 1.6 |
| Sample B3 | 180 | 70 | 0.78 | 1.56 |
| Sample B4 | 200 | 60 | 0.6 | 1.2 |
| Sample B5 | 200 | 70 | 0.7 | 1.4 |
| Sample B6 | 200 | 100 | 1.0 | 2.0 |
| Sample B7 | 250 | 90 | 0.72 | 1.44 |

Table 3 shows the samples having a light intensity peak at an angle range of less than 65° or more than 75°.

TABLE 3

| | Length of | | | |
|---|---|---|---|---|
| | one side | Thickness | | |
| Sample name | (μm) | Dx (μm) | tanθ | Ssub/Sdm |
| Sample C1 | 200 | 50 | 0.5 | 1.0 |
| Sample C2 | 150 | 90 | 1.2 | 2.4 |
| Sample C3 | 500 | 140 | 0.56 | 1.12 |

In sample B6, the maximum value appeared at an angle range of 65° to 75° in light distribution characteristics. However, in sample A4, the maximum value appeared at an angle smaller than 65°. Therefore, it is found that the maximum intensity value appears at an angle of 65° or more when tan(θ) is 1.0 or less. In sample B4, the maximum intensity value existed at an angle range of 65° to 75°. In sample C1, the maximum intensity value appeared at an angle of larger than 75°. Thus, it is found that the maximum intensity value appears at an angle of 75° or less when tan θ is 0.6 or more. The ranges of the equations (1) and (3) were determined in this way.

Samples A3, B1, B2, B3, and B5 have the maximum intensity value at an angle closer to 70°. The conditions determined by these samples are the above conditions (2) and (4). It is clear from this that the ranges of the equations (2) and (4) are more preferable.

Thus, the light intensity has a peak in the vicinity of 70° from the normal direction X1 in the light-emitting device satisfying equations (1) and (3).

It was found in the calculation that the angle at which the light intensity has a peak depends on not the length of one side but the tan(θ) or Ssub/Sdm.

What is claimed is:

1. A semiconductor light-emitting device comprising:
a substrate having a first surface and a second surface, the second surface having a rectangular shape including a square shape;
an n-type semiconductor layer formed on the first surface of the substrate;
a light-emitting layer formed on the n-type semiconductor layer;
a p-type semiconductor layer formed on the light-emitting layer;
a dielectric multilayer film formed on the second surface of the substrate, the dielectric multilayer film having a light extraction surface;
a distributed bragg reflector at a position on the opposite side of the dielectric multilayer film when viewed from the light-emitting layer; and
wherein the length of a specific side of the rectangular shape is 50 μm to 250 μm, the specific side being defined as one side when the lengths of four sides specifying the rectangular shape are all equal, and defined as a long side when the lengths of four sides are different; and
when an area of a surface of the dielectric multilayer film on the second surface is defined as surface area Sdm, and a total area of four side surfaces of the semiconductor light-emitting device is defined as side surface area Ssub, the side surface existing between the second surface and a center plane of the light-emitting layer, the center plane passing a center point of the light-emitting layer and being parallel to the second surface, the surface area Sdm and the side surface area Ssub satisfy the following equation,
1.2≤Ssub/Sdm≤2.0, and
when a middle point of a side perpendicular to the specific side on the rectangular shape is defined as Q1, a line connecting the center point and the middle point Q1 is defined as M1, and an angle formed between the line M1 and the center plane is defined as θ, the θ satisfies the following equation.
0.6≤tan(θ)≤1.0

2. A semiconductor light-emitting device comprising:
a substrate having a first surface and a second surface, the second surface having a rectangular shape including a square shape;
an n-type semiconductor layer formed on the first surface of the substrate;
a light-emitting layer formed on the n-type semiconductor layer;
a p-type semiconductor layer formed on the light-emitting layer;
a dielectric multilayer film formed on the second surface of the substrate, the dielectric multilayer film having a light extraction surface;
a distributed bragg reflector at a position on the opposite side of the dielectric multilayer film when viewed from the light-emitting layer; and
wherein the length of a specific side of the rectangular shape is 50 μm to 250 μm, the specific side being defined as one side when the lengths of four sides specifying the rectangular shape are all equal, and defined as a long side when the lengths of four sides are different; and
when a middle point of a side perpendicular to the specific side on the rectangular shape is defined as Q1, a line connecting a center point of the light-emitting layer and the middle point Q1 is defined as M1, an angle formed between the line M1 and a center plane is defined as α, the center plane passing the center point and being parallel to the second surface, a middle point of the specific side on the rectangular shape is defined as Q3, a line connecting the center point and the middle point Q3 is defined as M2, and an angle formed between the line M2 and the center plane is defined as β, the α and the β satisfy the following equations, respectively.
0.6≤tan(α)≤1.0
0.6≤tan(β)≤1.0

3. The semiconductor light-emitting device according to claim 2, wherein
the α and the β satisfy the following equations, respectively.
0.7≤tan(α)≤0.9
0.7≤tan(β)≤0.9

4. The semiconductor light-emitting device according to claim 1, wherein
the rectangular shape is the square shape.

5. The semiconductor light-emitting device according to claim 2, wherein
the rectangular shape is the square shape.

6. The semiconductor light-emitting device according to claim 2, wherein
the dielectric multilayer film has a characteristic of transmitting light at a center area thereof, and reflecting light at a region other than the center area.

7. The semiconductor light-emitting device according to claim 2, wherein
the semiconductor light-emitting device has a light distribution characteristic that the intensity of the light emitted from the light extraction surface has the maximum value at an emission angle range of 65° to 75°.

8. The semiconductor light-emitting device according to claim 2, wherein
the device comprises a metal reflecting layer formed on the distributed bragg reflector.

9. The semiconductor light-emitting device according to claim 2, wherein
the device comprises an n-electrode electrically connected to the n-type semiconductor layer and a p-electrode electrically connected to the p-type semiconductor layer; and
the n-electrode and the p-electrode cover a part of the side surface of the substrate.
